(19) United States
(12) Patent Application Publication
(10) Pub. No.: US 2013/0188428 A1
(43) Pub. Date: Jul. 25, 2013

(54) APPARATUSES, CIRCUITS, AND METHODS FOR REDUCING METASTABILITY IN LATCHES

(71) Applicant: Yantao Ma, Boise, ID (US)

(72) Inventor: Yantao Ma, Boise, ID (US)

(73) Assignee: Micron Technology, Inc., Boise, ID (US)

(21) Appl. No.: 13/358,455

(22) Filed: Jan. 25, 2012

(51) Int. Cl. G11C 7/10; H03K 3/3562; H03K 3/037

(52) U.S. Cl. 365/189.05; 327/199; 327/202

(57) ABSTRACT

Apparatuses, circuits, and methods are disclosed for reducing metastability in latches. In one such example apparatus, a circuit is configured to provide substantially complementary first and second signals and a latch stage is configured to latch the first and second signals. The latch stage includes a feedback circuit configured to provide positive feedback between the latched first and second signals.

### TECHNICAL FIELD

Embodiments of the invention relate generally to integrated circuits, and more particularly, in one or more of the illustrated embodiments, to reducing metastability in latches.

### BACKGROUND OF THE INVENTION

Metastability is a reliability concern in latches (e.g., flip-flops) where a plurality of different signals are provided to a circuit at the same or at nearly the same time. In a rising-edge triggered master-slave flip-flop, for example, if an input signal transitions right before a rising clock edge and violates the setup time of the flip-flop, if the input signal transitions at the same time as the rising clock edge, or if the input signal transitions right after the rising clock edge and violates the hold time of the flip-flop, then the flip-flop may at least temporarily enter a metastable state. The metastable state may be that one or more nodes of the flip-flop are at an invalid logic level (e.g., somewhere between a logic high and a logic low). The invalid logic level may result from the one or more nodes not being fully charged or discharged when the flip-flop latches the input signal at the rising clock edge because, for example, the one or more nodes did not get fully pulled-up or fully pulled-down.

When a latch, such as a flip-flop, enters a metastable state, the output of the latch may be incorrect in that it does not correspond to the input signal provided to the latch. The output may, for example, linger at an invalid logic level for an unacceptable period of time. Alternatively, or in addition to the output lingering at an invalid logic level, the output may not correctly correspond to the input signal because the output may transition too early or too late (i.e., have an incorrect phase). As an example, if the input signal to the flip-flop rises before the rising edge of the first clock cycle and falls before the rising edge of the fourth clock cycle, the output signal of the flip-flop should generally rise at the second clock cycle and fall at the fifth clock cycle, thus having a pulse width of four clock periods. However, if the flip-flop enters a metastable state (because, for example, the rising or falling edges of the input signal violate the setup or hold time of the flip-flop), the output may rise earlier or later than the second clock cycle and/or may fall earlier or later than the fifth clock cycle. In some cases, the width of the output pulse will still be four clock periods even if the phase of the output pulse is incorrect, but in other cases, the width of the output pulse may be shorter or longer than four clock periods. The lingering, the incorrect phase, and/or the incorrect pulse width resulting from the metastability may cause unintended operation of a circuit or apparatus that receives the output of the flip-flop.

The conventional approach to preventing unintended operation resulting from metastability in a latch includes chaining one or more flip-flops in series to help prevent lingering output signals from propagating to a subsequent circuit. Although such serial chaining of flip-flops may reduce the likelihood that the output signal of the serial chain lingers, this approach generally does little to correct the incorrect phase and/or the incorrect pulse width that may occur when a latch experiences metastability because it does not address the root cause of the metastability (e.g., latch nodes that do not get fully charged or discharged before the flip-flop latches) and instead simply mitigates some of the consequences from when a flip-flop experience metastability. Furthermore, serial chaining of flip-flops tends to consume power, present additional clock and signal loading, and add delay to a signal path, all of which may be undesirable in some cases.

### BRIEF DESCRIPTION OF THE DRAWINGS

FIG. 1 is a block diagram of an apparatus according to an embodiment of the present invention.

FIG. 2A is a schematic diagram of a differential signal generator according to an embodiment of the invention.

FIG. 2B is a schematic diagram of a differential signal generator according to an embodiment of the invention.

FIG. 3A is a block diagram of a single stage latch according to an embodiment of the invention.

FIG. 3B is a block diagram of a master stage and a slave stage of a latch according to an embodiment of the invention.

FIG. 4 is a schematic diagram of a master stage and slave stage of a latch according to an embodiment of the invention.

FIG. 5 is a schematic diagram of a master stage and slave stage of a latch according to an embodiment of the invention.

FIG. 6 is a block diagram of a memory according to an embodiment of the invention.

### DETAILED DESCRIPTION

Certain details are set forth below to provide a sufficient understanding of embodiments of the invention. However, it will be clear to one skilled in the art that embodiments of the invention may be practiced without these particular details. Moreover, the particular embodiments of the present invention described herein are provided by way of example and should not be used to limit the scope of the invention to these particular embodiments. In other instances, well-known circuits, control signals, timing protocols, and software operations have not been shown in detail in order to avoid unnecessarily obscuring the invention.

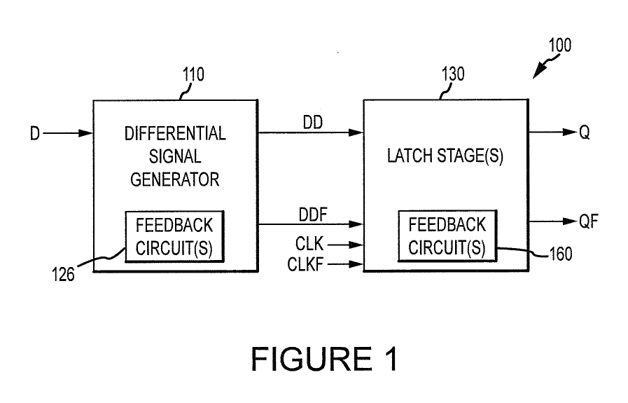

FIG. 1 illustrates an apparatus 100 according to an embodiment of the invention. The apparatus 100 receives an input signal D and a latching signal CLK. The input signal D may be asynchronous in some embodiments, but may also be synchronous in some embodiments. The latching signal CLK may be a clock signal in some embodiments, although in other embodiments, a gating signal or any other type of latching signal may be used. As illustrated in FIG. 1, in some embodiments the apparatus 100 also receives another latching signal CLKF. In other embodiments, however, the apparatus 100 may only receive the latching signal CLK and not CLKF. In apparatuses that only receive the latching signal CLK, the latching signal CLKF may in some embodiments be internally generated responsive to the latching signal CLK. The latching signal CLKF may in some embodiments be substantially complementary to the latching signal CLK. The apparatus 100 provides an output signal Q, and in some embodiments may also provide another output signal QF. The output signal QF may in some embodiments be substantially complementary to the output signal Q.

The apparatus 100 includes a differential signal generator 110 and one or more latch stage(s) 130. As explained in more detail below, the differential signal generator 110 and the one or more latch stage(s) 130 may help reduce metastability in the apparatus 100 and may help prevent the output Q of the apparatus 100 from lingering and/or from having an incorrect phase and/or an incorrect pulse width as compared with the input signal.

The differential signal generator 110 receives the input signal D and provides a first signal DD and a second signal DDF. The differential signal generator 110 may provide the first signal DD at least partially in response to the input signal D, and may also provide the second signal DDF at least partially in response to the input signal D. The second signal DDF may be substantially complementary to the first signal DD. The signals DD, DDF may be substantially complementary to one another in that they may be, for example, +/−10 degrees out of phase with each other's complement. In other words, the signal DD may be slightly (e.g. +/−10 degrees) out of phase with the complement of the signal DDF and the signal DDF may be slightly (e.g. +/−10 degrees) out of phase with the complement of the signal DD, or the rising edge of the signal DD may be slightly out of phase (e.g., +/−10 degrees) with the falling edge of the signal DDF and the falling edge of the signal DD may be slightly out of phase (e.g., +/−10 degrees) with the rising edge of the signal DDF. In some embodiments, the first and second signals DD, DDF may be used for differential signaling.

In some embodiments, the differential signal generator 110 may be configured to ensure that the first signal DD is slightly (e.g., +/−10 degrees) out of phase with the complement of the second signal DDF and that the second signal DDF is slightly (e.g., +/−10 degrees) out of phase with the complement of the first signal DD. When the first and second signals DD, DDF are thus out of phase with each other's complement, the probability that both will cause a respective node in the (subsequent) latch stage(s) 130 to enter a metastable state may be very low. As explained below, because the probability is very low that both the first and the second signals DD, DDF will cause a respective node in the latch stage(s) 130 to enter a metastable state, the first or second signal DD, DDF may, after being latched into its respective node, help prevent a metastable state in the other node.

The differential signal generator 110 in some embodiments includes one or more feedback circuit(s) 126. The feedback circuit(s) may help ensure that the first and second signals DD, DDF are substantially complementary to one another. The differential signal generator 110 may include none, one, or a plurality of feedback circuits 126.

The one or more latch stage(s) 130 may include one or more input circuits (not illustrated in FIG. 1) that receive and latch the first and second signals DD, DDF. For example, in apparatuses 100 with only a single latch stage 130, the single latch stage 130 latches the first and second signals DD, DDF, and provides the output signal Q and the output signal QF responsive to the latched first and second signals DD, DDF, respectively. As another example, in apparatuses 100 with more than a single latch stage 130, the first latch stage 130 latches the first and second signals DD, DDF, and in response provide third and fourth signals (not illustrated in FIG. 1) to a second latch stage 130, which in turn provides the output signal Q and the output signal QF responsive to the latched third and fourth signals, respectively.

One or more of the one or more latch stage(s) 130 may include one or more feedback circuit(s) 160. The one or more feedback circuit(s) 160 may provide feedback between the latched signals in the latch stage 130 that includes the feedback circuit(s) 160. For example, with reference to FIG. 1, the feedback circuit 160 provides feedback between the latched first signal and the latched second signal. As described in more detail in embodiments below, the feedback circuit 160 may include one or more inverters and/or one or more cross coupling lines that couple the latched first signal and the latched second signal. The feedback circuit 160 may help resolve metastability in one of the latched signals by, for example, reinforcing the state of the one latched signal from the other latched signal. The feedback circuit 160 may also help preserve the respective latched signals at their appropriate logic levels. In some embodiments, each latch stage 130 includes a feedback circuit 160, whereas in other embodiments one or more latch stage(s) 130 may each include a plurality of feedback circuits 160.

In some embodiments, the apparatus 100 may not include a differential signal generator. For example, if the apparatus receives signals D, DF (not illustrated in FIG. 1) from a circuit that are already substantially complementary to one another, then these signals may be provided to the one or more latch stage(s) 130 without the need for a differential signal generator to generate yet another signal. This may be the case if the signals D, DF are provided from a circuit that generates differential signals, including for example the apparatus 100.

Depending on the configuration of the one or more latch stage(s) 130, the apparatus 100 may be used for a variety of purposes. For example, when there is only a single latch stage 130, the apparatus 100 may be used as a level sensitive latch that is transparent when the CLK signal is low and maintains a captured data value when the CLK signal is high, or vice versa. As another example, when the apparatus 100 includes a master stage 130 and a slave stage 130, the apparatus 100 may be used as a rising-edge triggered master-slave flip-flop. In other embodiments, the one or more latch stage(s) 130 may be configured to allow the apparatus 100 to be used as a falling-edge triggered master-slave flip-flop, a T flip-flop, a JK flip-flop, a gated D latch, and so forth.

The apparatus 100 may be used for data synchronization. For example, an asynchronous signal may be provided as the input signal D to the apparatus 100, and the apparatus 100 may help synchronize the input signal with the CLK signal without experiencing metastability. The asynchronous signal may be asynchronous in that it is unrelated to the CLK signal—for example, the asynchronous signal may come from an external output with unknown timing, or may come from a circuit with a different clock domain than the CLK signal. The apparatus 100 may, however, also be used in partially or fully synchronous circuits as well.

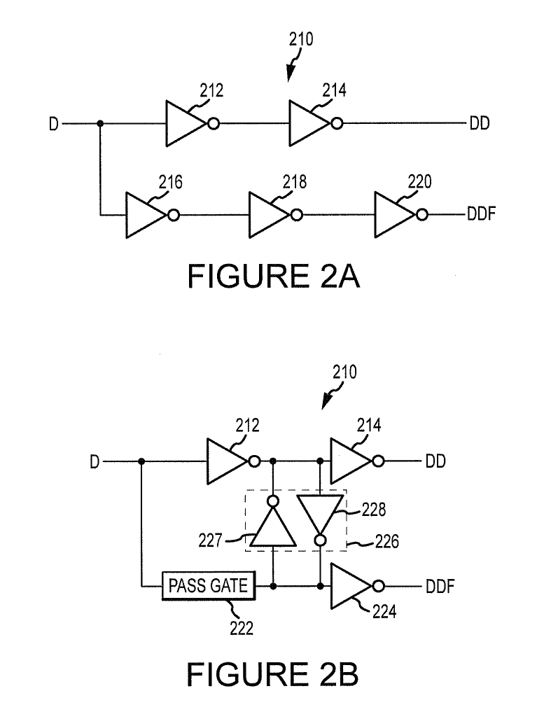

FIG. 2A illustrates an embodiment of a differential signal generator 210 (which may also be called a phase splitter) that may be used for the differential signal generator 110 in FIG. 1. The differential signal generator 210 in FIG. 2A receives the input signal D, and propagates this received signal through two different paths of inverters. As illustrated in FIG. 2A, the input signal D is propagated through first and second inverters 212, 214 in order to provide the first signal DD, and is propagated through third, fourth, and fifth inverters 216, 218, 220 in order to provide the second signal DDF. The first and second signals DD, DDF may be differential signals.

The inverters 212, 214, 216, 218, 220 may be sized (e.g., designed with an appropriate drive strength) such that the propagation delay of the two different paths is substantially the same (e.g., within +/−10%) and/or so that the DD and DDF signals are substantially complementary to one another (e.g., +/−10 degrees out of phase with each other's complement). In some embodiments, the inverters 212, 214, 216, 218, 220 may be designed such that the propagation delay is equal, but, due to process variations during manufacturing, the propagation delay of the two paths may be slightly different (e.g., within +/−10%). In other embodiments, however, the inverters 212, 214, 216, 218, 220 may be designed so that the propagation delay of the two paths is slightly different.

FIG. 2B illustrates another embodiment of a differential signal generator 210. The differential signal generator 210 illustrated in FIG. 2B may be used for the differential signal generator 110 in FIG. 1. Like the differential signal generator 210 illustrated in FIG. 2A, the differential signal generator 210 illustrated in FIG. 2B receives the input signal D, and propagates this received signal through two different paths. As illustrated in FIG. 2B, the input signal D is propagated through first and second inverters 212, 214 in order to provide the first signal DD, and is propagated through a pass gate 222 and a third inverter 224 in order to provide the second signal DDF. The inverters 212, 214, 224 and the pass gate 222 may be sized such that the propagation delays of the two different paths are substantially the same (e.g., within +/−10%) and/or so that the DD and DDF signals are substantially complementary to one another (e.g., +/−10 degrees out of phase with each other's complement).

The differential signal generator 210 illustrated in FIG. 2B also includes a feedback circuit 226. The feedback circuit 226 includes two inverters 227, 228 that couple the node between the inverters 212 and 214, and the node between the pass gate 222 and the inverter 224. The feedback circuit 226 may provide positive feedback between these two nodes of the differential signal generator 210 and/or may help ensure that the DD and DDF signals are complementary to one another (e.g., opposite one another—so if DD is a logic low, DDF is a logic high, and vice versa). In general, a differential signal generator 210 may include none, one, or a plurality of feedback circuits 226, and the feedback circuits 226 may couple two or more nodes of the differential signal generator 210.

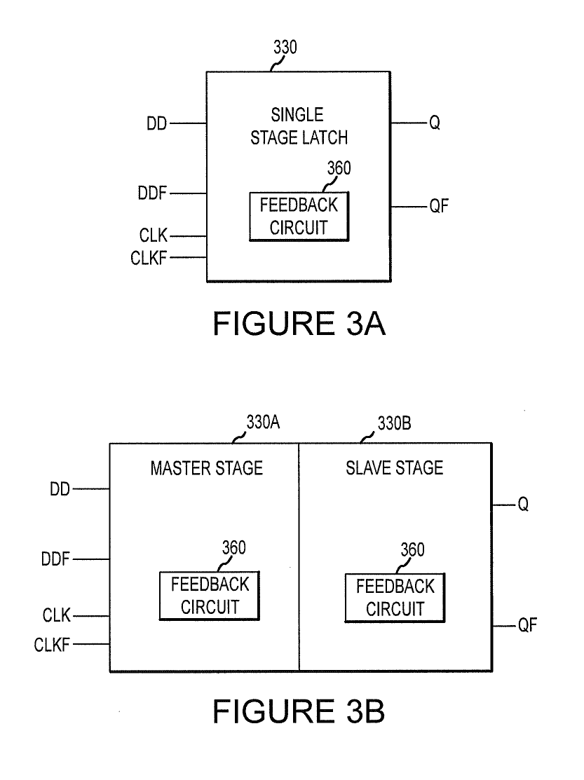

FIG. 3A illustrates a single stage latch 330 that may be used in the apparatus 100, and FIG. 3B illustrates a multi-stage latch with a master stage 330A and a slave stage 330B that may be used in the apparatus 100. As explained above, any number of latch stages may be used. Each stage 330, 330A, 330B may include a feedback circuit 360.

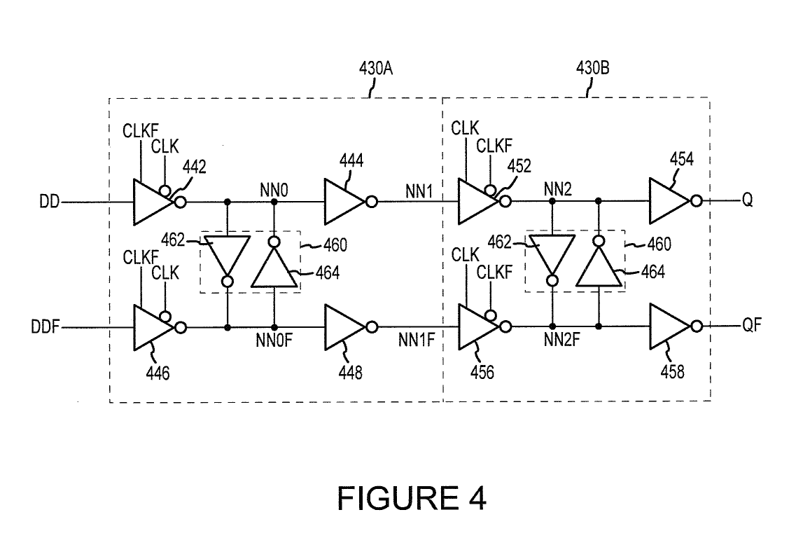

FIG. 4 illustrates a multi-stage latch with a master stage 430A and a slave stage 430B. The master and slave stages 430A, 430B may be used, for example, as the latch stage(s) 130 of the apparatus 100 in FIG. 1 and/or the master stage 330A and slave stage 330B in FIG. 3B. The master stage 430A may receive the first and second signals DD, DDF from a differential signal generator, such as the differential signal generators 110, 210, 210 illustrated in FIGS. 1, 2A, and 2B. As described above, the master stage 430A may instead receive the first and second signals DD, DDF from a different circuit that provides substantially complementary signals D, DF. The master stage 430A may provide signals NN1 and NN1F to the slave stage 430B.

The master stage 430A includes two input circuits 442, 446 configured to selectively provide the first and second signals DD, DDF to respective nodes NN0 and NN0F. The input circuits 442, 446 receive latching signals CLK, CLKF. In some embodiments, the input circuits 442, 446 may include a latching element such as a tri-state inverter, but in other embodiments, a different latching element may be used. The master stage 430A may also in some embodiments include inverters 444, 448 that invert the signals latched into nodes NN0, NN0F, and provide the inverted latched signals as the signals NN1, NN1F, respectively.

The master stage 430A also includes a feedback circuit 460 configured to provide positive feedback between node NN0 and node NN0F. As illustrated in FIG. 4, the feedback circuit 460 includes two inverters 462, 464 that inversely couple node NN0 and node NN0F. The feedback circuit 460 may help ensure that the latched signals on nodes NN0 and NN0F are complementary (e.g., opposite one another—so if NN0 is a logic low, NN0F is a logic high, and vice versa) and may help prevent at least one of the input circuits 452, 456 of the slave stage 430B (described below) from entering a metastable state by preventing nodes NN0 and NN0F from lingering. The feedback circuit 460 may help drive nodes NN0 and NN0F to the appropriate fully-charged or fully-discharged logic level. The feedback circuit 460 may also help preserve the respective latched signals at their appropriate latched logic levels.

The input circuits 452, 456 of slave stage 430B are configured to selectively provide the signals NN1, NN1F to respective nodes NN2 and NN2F. The input circuits 452, 456 of the slave stage 430B also receive the CLK, CLKF signals also received by the input circuits 442, 446. The slave stage 430B may also in some embodiments include inverters 454, 458 that invert the signals latched into nodes NN2, NN2F, and provide the inverted latched signals as the output signals Q and QF, respectively.

The slave stage 430B also includes a feedback circuit 460 configured to provide positive feedback between node NN2 and node NN2F. As illustrated in FIG. 4, the feedback circuit 460 includes two inverters 462, 464 that inversely couple node NN2 and node NN2F. The feedback circuit 460 may help ensure that the latched signals on nodes NN2 and NN2F are complementary (e.g., opposite one another—so if NN2 is a logic low, NN2F is a logic high, and vice versa) and may help the output signals Q, QF to resolve quickly so as to avoid introducing metastable states in a subsequent data latch or other circuit to which the output signal Q and/or the output signal QF is provided. The feedback circuit may help prevent nodes NN2 and NN2F from lingering, and may help drive nodes NN2 and NN2F to the appropriate fully-charged or fully-discharged logic level. The feedback circuit 460 may also help preserve the respective latched signals at their appropriate latched logic levels.

In some embodiments, the feedback circuits 460 may have less drive strength than the input circuits 442, 446, 452, 456 and/or than the inverters 444, 448, 454, 458 in order to allow the input circuits and/or the inverters to overpower the feedback circuits 460 when new signals need to be latched into the respective nodes.

In operation, the DD and the DDF signals are provided through the input circuits 442, 446 to nodes NN0 and NN0F, respectively, when the CLK signal is low and/or when the CLKF signal is high. During this time the input circuits 442, 446 are “transparent” to the DD and DDF signals. When the CLK and/or CLKF signals transition high and low, respectively, however, the input circuits 442, 446 are no longer transparent and no longer provide the DD and DDF signals to nodes NN0 and NN0F. When the input circuits 442, 446 are tri-state inverters, as illustrated in FIG. 4, the input circuits 442, 446 may output a high impedance when the CLK signal is high and/or when the CLKF signal is low, allowing nodes NN0 and NN0F to float. The inverters 462, 464 of the feedback circuit 460 in the master stage 430A may help drive nodes NN0 and NN0F to complementary (e.g., opposite one another—so if NN0 is a logic low, NN0F is a logic high, and vice versa) logic levels in order to prevent or reduce the probability of the input circuits 452, 456 of the slave stage from entering into a metastable state. The inverters 462, 464 may accomplish this because they inversely couple nodes NN0 and NN0F. The inverters 444 and 448 in the master stage 430A may invert the signal present on nodes NN0 and NN0F and provide the inverted signals NN1 and NN1F to the slave stage 430B.

The input circuits 452, 456 in the slave stage 43QB are transparent when the CLK signal is high and/or when the CLKF signal is low and provide the NN1 and NN1F signals to nodes NN2 and NN2F. When the CLK and or CLKF signals transition low and high, respectively, however, the input circuits 452, 456 are no longer transparent and no longer provide the NN1 and NN1F signals to nodes NN2 and NN2F. When the input circuits 452, 456 are tri-state inverters, as illustrated in FIG. 4, the input circuits 452, 456 may output a high impedance when the CLK signal is low and/or when the CLKF signal is high, allowing nodes NN2 and NN2F to float. The inverters 462, 464 of the feedback circuit 460 in the slave stage 430B may help drive nodes NN2 and NN2F to complementary (e.g., opposite one another—so if NN0 is a logic low, NN0F is a logic high, and vice versa) logic levels in order to prevent or reduce the probability of introducing metastable states in a subsequent data latch or other circuit to which the output signal Q and/or the output signal QF is provided. The inverters 462, 464 may accomplish this because they inversely couple nodes NN2 and NN2F. The inverters 454 and 458 in the slave stage 430B may invert the signal present on nodes NN2 and NN2F and provide the output and output signals Q, QF.

In this manner, the master and slave stages 430A, 430B operate to provide functionality similar to a conventional rising-edge triggered master-slave flip-flop. Although not illustrated, the operational timing diagram for the master and slave stages 430A, 430B may be similar to an operational timing diagram for a conventional rising-edge triggered master-slave flip-flop.

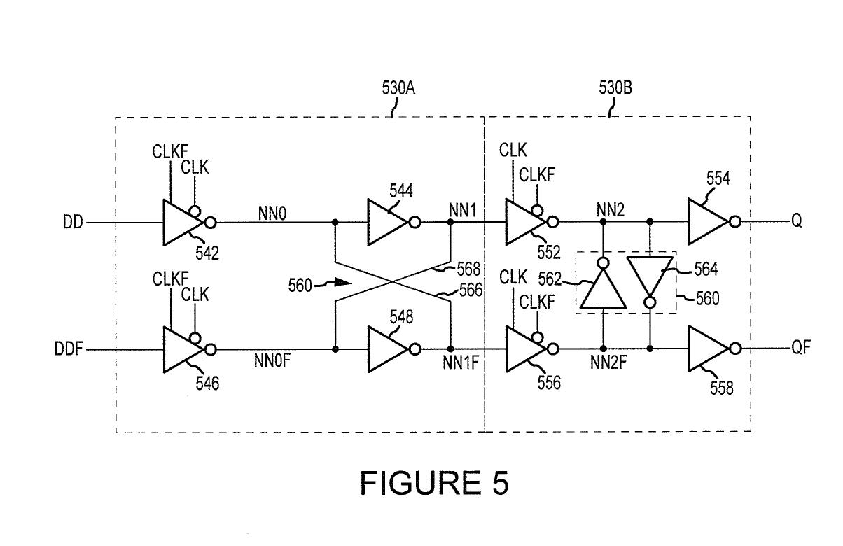

FIG. 5 illustrates another embodiment of a master stage 530A and a slave stage 530B. The master and slave stages 530A, 530B may be used, for example, as the latch stage(s) 130 of the apparatus 100 in FIG. 1, and may be similar to the master and slave stages 430A, 430B illustrated in FIG. 4 and described above, except that the master stage 530A in FIG. 5 has a different type of feedback circuit 560. The feedback circuit 560 in the master stage illustrated in FIG. 5 includes two cross coupling lines 566, 568, that cross couple the two paths of the master stage 530A. For example, the first cross coupling line 556 couples node NN0 to the output of the inverter 548 at node NN1F, and the second cross coupling line 556 couples node NN0F to the output of the inverter 544 at node NN1. The slave stage 530B illustrated in FIG. 5 may be similar to the slave stage 430B illustrated in FIG. 4, including a similar feedback circuit 560. In some embodiments, a feedback circuit having the configuration of the feedback circuit 560 may be used in the slave stage 530B.

The operation of the master and slave stages 530A, 530B illustrated in FIG. 5 may be similar to the operation of the master and slave stages 430A, 430B illustrated in FIG. 4. The different feedback circuit 560 in the master stage 530A in FIG. 5 may similarly prevent or reduce the probability of the input circuits 552, 556 of the slave stage 530B from entering into a metastable state. The feedback circuit 560 illustrated in the master stage 530A in FIG. 5, however, may help to reduce clock loading and may have a smaller size as compared with the feedback circuit 460 illustrated in FIG. 4. Nonetheless, in general, either embodiment of the feedback circuit 460, 560 may be used in any latch stage, and at any point along the latch stage. In some embodiments, both embodiments of the feedback circuit may even be used in a single latch stage.

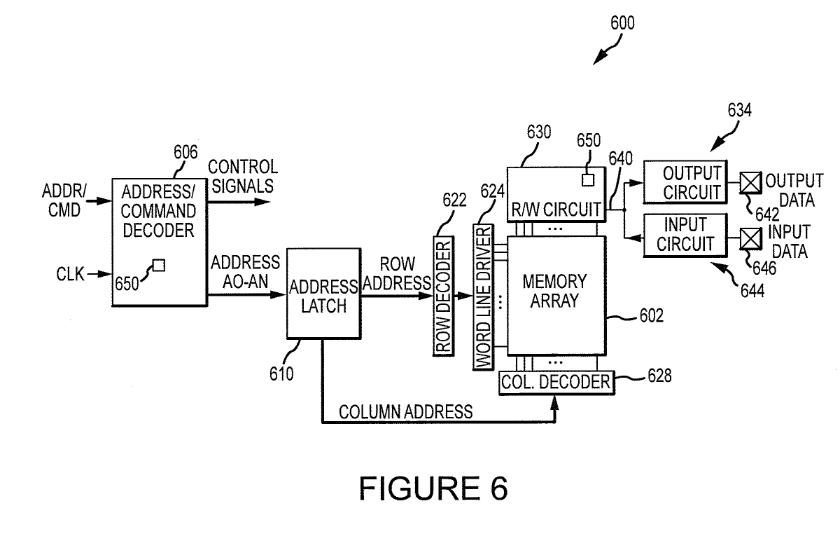

FIG. 6 illustrates a portion of a memory 600 according to an embodiment of the present invention. The memory 600 includes an array 602 of memory cells, which may be, for example, DRAM memory cells, SRAM memory cells, flash memory cells, or some other types of memory cells. The memory 600 includes an address/command decoder 606 that receives memory commands and addresses through an ADDR/CMD bus. The address/command decoder 606 provides control signals, based on the commands received through the ADDR/CMD bus. The address/command decoder 606 also provides row and column addresses to the memory 600 through an address bus and an address latch 610. The address latch then outputs separate column addresses and separate row addresses.

The row and column addresses are provided by the address latch 610 to a row address decoder 622 and a column address decoder 628, respectively. The column address decoder 628 selects bit lines extending through the array 602 corresponding to respective column addresses. The row address decoder 622 is connected to word line driver 624 that activates respective rows of memory cells in the array 602 corresponding to received row addresses. The selected data line (e.g., a bit line or bit lines) corresponding to a received column address are coupled to a read/write circuitry 630 to provide read data to a data output circuit 634 via an input-output data bus 640. An output pad 642 coupled to the data output circuit 634 is used for electrically coupling to the memory 600. Write data are provided to the memory array 602 through a data input circuit 644 and the memory array read/write circuitry 630. An input pad 646 coupled to the data input circuit 642 is used for electrically coupling to the memory 600. The address/command decoder 606 responds to memory commands and addresses provided to the ADDR/CMD bus to perform various operations on the memory array 602. In particular, the address/command decoder 606 is used to provide control signals to read data from and write data to the memory array 602.

The memory 600 may include one or more apparatuses 650 including latch stages according to an embodiment of the invention. Although the apparatuses 650 may be used in any number of locations within the memory 600, FIG. 6 illustrates an apparatus 650 in the address/command decoder 606 and in the read/write circuit 630. The apparatus 650 in the address/command decoder 606 may help synchronize signals received by the memory from a controller, and the apparatus 650 in the read/write circuit 630 may help synchronize data that is read out of the memory array 602. Of course, other apparatuses 650 according to an embodiment of the invention may also be used in different locations in the memory 600 illustrated in FIG. 6.

From the foregoing it will be appreciated that, although specific embodiments of the invention have been described herein for purposes of illustration, various modifications may be made without deviating from the spirit and scope of the invention. For example, FIGS. 1, 3, 4, and 5 illustrate embodiments of a latch stage, FIGS. 1, 2A, and 2B illustrate embodiments of a differential signal generator, and FIGS. 1, 2, 3, 4, and 5 illustrate embodiments of a feedback circuit. However, other latch stages, other differential signal generators, and/or other feedback circuits may be used, which are not limited to having the same design, and may be of different designs and include circuitry different from the circuitry in the embodiments illustrated in these Figures.

As mentioned, any number of latch stages may be used, including one, two, three, and more. Also, the latch stages may be different from one another in some embodiments, such as a master latch and a slave latch as described above. Also as mentioned, one or more feedback circuits may be used in the differential signal generator and/or in one or more of the latch stages. Also, although the input circuits are illustrated as tri-state inverters in FIGS. 4 and 5, other types of input circuits may be used in place of or in addition to the tri-state inverters.

Also, although not illustrated in the figures, the circuits, differential signal generators, the one or more latch stages, the feedback circuits, and/or other circuits may be provided with reset signals, clear signals, preset signals, and so forth.

As used herein, an apparatus may refer to a number of different things, such as circuitry, a memory device, a memory system (e.g., SSD) or an electronic device or system (e.g., a computer, smart phone, server, etc.).

Accordingly, the invention is not limited except as by the appended claims.

What is claimed is:

1. An apparatus, comprising:
a circuit configured to provide substantially complementary first and second signals; and
a latch stage configured to latch the first and second signals, the latch stage comprising a feedback circuit configured to provide positive feedback between the latched first and second signals.

2. The apparatus of claim 1, wherein the circuit is a differential signal generator.

3. The apparatus of claim 1, wherein the feedback circuit comprises two inverters inversely coupling the latched first and second signals.

4. The apparatus of claim 3, wherein the feedback circuit is configured to drive the latched first and second signals to the appropriate fully-charged or fully-discharged logic level.

5. The apparatus of claim 1, wherein the feedback circuit comprises two cross coupling lines cross coupling the latched first and second signals.

6. The apparatus of claim 1, wherein the differential signal generator and the latch stage form a level sensitive latch.

7. An apparatus, comprising:
a differential signal generator configured to provide, responsive to an input signal, a first signal and a second signal, the first signal substantially complementary to the second signal;
a master stage configured to latch the first signal with a first latching element and to latch the second signal with a second latching element, the master stage further configured to provide a third signal responsive to the latched first signal and a fourth signal responsive to the latched second signal;
a slave stage coupled to the master stage and configured to latch the third signal with a third latching element and to latch the fourth signal with a fourth latching element, the slave stage configured to provide a first output signal responsive to the latched third signal and a second output signal responsive to the latched fourth signal;
a first feedback circuit configured to provide positive feedback between the latched first signal and the latched second signal; and
a second feedback circuit configured to provide positive feedback between the latched third signal and the latched fourth signal.

8. The apparatus of claim 7, wherein the first, second, third, and fourth latching elements comprise tri-state inverters.

9. The apparatus of claim 7, wherein the first feedback circuit comprises two inverters inversely coupling a first output of the first latching element with a second output of the second latching element.

10. The apparatus of claim 9 wherein a first drive strength of the two inverters is less than a second drive strength of the first and second latching elements.

11. The apparatus of claim 7, wherein the first latching element provides a third output, the second latching element provides a fourth output, a first inverter provides a fifth output responsive to the third output, a second inverter provides a sixth output responsive to the fourth output, and the feedback circuit comprises a first cross coupling line coupling the third output with the sixth output and a second cross coupling line coupling the fourth output with the fifth output.

12. The apparatus of claim 7, wherein the apparatus further comprises a DRAM memory, the DRAM memory comprising the differential signal generator, the master stage, the slave stage, and the first and second feedback circuits.

13. The apparatus of claim 7, wherein the differential signal generator comprises a first path with a first and second inverter and a second path with a third, fourth, and fifth inverter.

14. The apparatus of claim 7, wherein the differential signal generator comprises a first path with a first and second inverter and a second path with a pass gate and a third inverter.

15. The apparatus of claim 14, wherein a propagation delay of the first path is substantially the same as the propagation delay of the second path.

16. The apparatus of claim 15, wherein the differential signal generator comprises a feedback circuit.

17. The apparatus of claim 16, wherein the feedback circuit comprises two inversely coupling inverters.

18. A method for reducing metastability in latches, comprising:
receiving a first signal and a second signal, the first signal substantially complementary to the second signal; and
latching the first and second signals in a latch stage;
providing feedback between the latched first signal and the latched second signal using a feedback signal.

19. The method of claim 18, wherein latching the first and second signals comprises latching the first signal at a first node in the latch stage and latching the second signal at a second node in the latch stage, and wherein providing feedback comprises providing positive feedback between the first and second nodes.

20. The method of claim 18, wherein latching the first and second signals comprises latching the first signal at a first node in the latch stage and latching the second signal at a second node in the latch stage, the method further comprising:
inverting the first latched signal and providing the inverted first latched signal to a third node;
inverting the second latched signal and providing the inverted second latched signal to a fourth node;
cross coupling the first node with the fourth node; and
cross coupling the second node with the third node.

21. The method of claim 18, wherein latching the first and second signals comprises latching the first and second signals in the latch stage by a clock signal.

22. The method of claim 18, wherein the latch stage is a first latch stage and the feedback circuit is a first feedback circuit, and further comprising:
providing a third signal responsive to the latched first signal and a fourth signal responsive to the latched second signal;
latching the third and fourth signals in a second latch stage; and
providing feedback between the latched third signal and the latched fourth signal using a second feedback circuit.

23. A method, comprising:
providing asynchronous differential signals;
latching the asynchronous differential signals; and
resolving metastability in one of the latched differential signals by coupling the one latched differential signal with the other of the latched differential signals through a feedback circuit.

24. The method of claim 23, wherein the asynchronous differential signals are provided responsive to an asynchronous input signal.

25. The method of claim 23, wherein the latched differential signals are provided to a circuit, further comprising preventing the metastability in the one latched differential signal from propagating to the circuit.

26. The method of claim 23, further comprising: providing a synchronous output signal responsive to the one latched differential signal.

27. The method of claim 23, wherein the asynchronous differential signals are latched at a rising edge of a clock signal.

28. An apparatus comprising:
a signal generator configured to receive an input signal and provide first and second signals at least partially in response to the input signal, wherein the first and second signals are substantially complementary to one another, and wherein the differential signal generator is configured to ensure that the first and second signals are out of phase with each other's complement; and
a latch configured to receive a latching signal and the first and second signals, and to provide an output signal at least partially in response thereto.

29. The apparatus of claim 28, wherein the signal generator includes a feedback circuit.

30. The apparatus of claim 28, wherein the latch comprise a single stage latch.

31. The apparatus of claim 28, wherein the latch comprises a multi-stage latch.

32. The apparatus of claim 28, wherein the latching signal comprises a clock signal.

33. The apparatus of claim 28, wherein the latch includes an input circuit configured to receive and latch the first and second signals.

34. The apparatus of claim 33, wherein the latch includes a feedback circuit configured to provide feedback between the first and second signals.

35. The apparatus of claim 28, wherein the signal generator comprises a differential signal generator.
